(19) United States
(12) Patent Application Publication
(10) Pub. No.: US 2025/0359387 A1
(43) Pub. Date: Nov. 20, 2025

(54) OPTOELECTRONIC DEVICE AND METHOD FOR OPERATING AN OPTOELECTRONIC DEVICE

(71) Applicant: ams-OSRAM AG, PREMSTAETTEN (AT)

(72) Inventors: Alexander WILM, Regensburg (DE); Christopher L. EICHELBERGER, COMMERCE TWP., MI (US)

(73) Assignee: ams-OSRAM AG, PREMSTAETTEN (AT)

(21) Appl. No.: 18/867,665

(22) PCT Filed: Apr. 19, 2023
(86) PCT No.: PCT/EP2023/060123

§ 371 Date: Nov. 20, 2024

Related U.S. Application Data
(60) Provisional application No. 63/345,745, filed on May 25, 2022.

(51) Int. Cl. H10F 55/255; G01D 5/26; H10F 77/40; H10F 77/50

(52) U.S. Cl. CPC H10F 55/255; G01D 5/26; H10F 77/413; H10F 77/50

(57) ABSTRACT

An optoelectronic device is provided, the optoelectronic device including a radiation source that is configured to emit electromagnetic radiation, a sensor that is configured to detect electromagnetic radiation, a carrier on which the radiation source and the sensor are arranged, and a deflection element, wherein the sensor is arranged between the deflection element and the carrier, the radiation source has a main plane of extension that extends parallel to a main plane of extension of the sensor, and the deflection element has at least one deflection surface that encloses an angle of more than 0° with the main plane of extension of the sensor. Furthermore, a method for operating an optoelectronic device is provided.

### CROSS-REFERENCE TO RELATED APPLICATIONS

The present application is a national stage entry from International Application No. PCT/EP2023/060123, filed on Apr. 19, 2023, published as International Publication No. WO 2023/227295 A1 on Nov. 30, 2023, and claims the benefit of U.S. Provisional Patent Application No. 63/345,745, filed May 25, 2022, the disclosures of all of which are hereby incorporated by reference in their entireties.

### FIELD

An optoelectronic device and a method for operating an optoelectronic device are provided.

### BACKGROUND

For optoelectronic devices it is often required to monitor the wavelength and/or intensity of electromagnetic radiation emitted by the device. For this purpose, the device can comprise one or more than one optical sensor. It is also possible that an external or several external optical sensors are employed. The sensors need to be positioned in such a way that electromagnetic radiation emitted by the device reaches the sensors.

It is an objective to provide an optoelectronic device that has a compact setup. It is further an objective to provide a method for operating an optoelectronic device that has a compact setup.

These objectives are achieved by the subject matter of the independent claims. Further developments and embodiments are described in dependent claims.

### SUMMARY

According to at least one embodiment of the optoelectronic device, the optoelectronic device comprises a radiation source that is configured to emit electromagnetic radiation. The radiation source can be configured to emit electromagnetic radiation during operation. The radiation source can be configured to emit electromagnetic radiation during operation of the radiation source. The radiation source can be a light-emitting diode. It is also possible that the radiation source is a laser device. In this case, the radiation source is configured to emit laser radiation. The radiation source can be configured to emit electromagnetic radiation within a wavelength range. For example, the radiation source is configured to emit radiation in the ultraviolet (UV) range, in particular in the UV-C range.

According to at least one embodiment of the optoelectronic device, the optoelectronic device comprises a sensor that is configured to detect electromagnetic radiation. The sensor can be an optical sensor. For example, the sensor comprises a photodiode or a photodetector. The sensor can be configured to detect electromagnetic radiation during operation of the sensor. The sensor can be configured to detect electromagnetic radiation within a predefined wavelength range, for example in the UV range. The sensor can be configured to determine the wavelength of electromagnetic radiation reaching the sensor. The sensor can be configured to determine the wavelength of electromagnetic radiation reaching the sensor within a predefined wavelength range of the incoming radiation. It is also possible that the sensor is configured to determine the intensity of electromagnetic radiation reaching the sensor. The sensor can be configured to provide a sensor signal. The sensor can comprise an interference filter or a dichroic filter.

According to at least one embodiment of the optoelectronic device, the optoelectronic device comprises a carrier on which the radiation source and the sensor are arranged. The radiation source and the sensor can be arranged adjacent or next to each other on the carrier. The carrier can have a main surface. The radiation source and the sensor can be arranged at the main surface. The carrier can have a main plane of extension. The carrier can comprise a printed circuit board (PCB). The radiation source and the sensor can thus be arranged on the same PCB.

According to at least one embodiment of the optoelectronic device, the optoelectronic device comprises a deflection element. The deflection element can be configured to deflect electromagnetic radiation impinging on the deflection element. This can mean, that the deflection element is configured to change the main direction of propagation of electromagnetic radiation impinging on the deflection element.

According to at least one embodiment of the optoelectronic device, the sensor is arranged between the deflection element and the carrier. This can mean, that the sensor is arranged on the carrier and the deflection element is arranged above the sensor. The sensor can be arranged between the deflection element and the carrier along a vertical direction that extends perpendicular to the main plane of extension of the carrier. The deflection element can be arranged spaced apart from the sensor.

According to at least one embodiment of the optoelectronic device, the radiation source has a main plane of extension that extends parallel to a main plane of extension of the sensor. The main plane of extension of the radiation source can extend parallel to the main plane of extension of the carrier. The main plane of extension of the sensor can extend parallel to the main plane of extension of the carrier.

According to at least one embodiment of the optoelectronic device, the deflection element has at least one deflection surface that encloses an angle of more than 0° with the main plane of extension of the sensor. This can mean, that the deflection surface extends within a plane that encloses an angle of more than 0° with the main plane of extension of the sensor. The deflection surface can thus be tilted with respect to the main plane of extension of the sensor. The deflection element can comprise several deflection surfaces that enclose an angle of more than 0° with the main plane of extension of the sensor. The deflection surfaces can form the surface of a free-form mirror or another type of mirror. If the deflection element comprises only one deflection surface, the deflection surface can be the surface of a mirror.

According to at least one embodiment of the optoelectronic device, the optoelectronic device comprises a radiation source that is configured to emit electromagnetic radiation, a sensor that is configured to detect electromagnetic radiation, a carrier on which the radiation source and the sensor are arranged, and a deflection element, wherein the sensor is arranged between the deflection element and the carrier, the radiation source has a main plane of extension that extends parallel to a main plane of extension of the sensor, and the deflection element has at least one deflection surface that encloses an angle of more than 0° with the main plane of extension of the sensor.

The sensor of the optoelectronic device can be employed to monitor electromagnetic radiation emitted by the radiation source. For example, the sensor can be employed to determine the wavelength or the wavelengths of electromagnetic radiation emitted by the radiation source. Since the main plane of extension of the radiation source extends parallel to the main plane of extension of the sensor, electromagnetic radiation emitted by the radiation source is not emitted into the direction of the sensor. However, the deflection element is employed to direct electromagnetic radiation which is emitted by the radiation source towards the sensor. The radiation source can be configured to emit electromagnetic radiation in different directions. The deflection element is placed in such a way that a part of the electromagnetic radiation emitted by the radiation source can directly reach the deflection surface. At the deflection surface the electromagnetic radiation is reflected to the sensor. In this way, a uniform irradiance of the sensor is achieved. The electromagnetic radiation that reaches the sensor is in most cases not required for the desired application. The electromagnetic radiation that reaches the sensor can have a main propagation direction that is encloses an angle of less than 20° with the main plane of extension of the carrier. For most applications, electromagnetic radiation with larger angles between the main propagation direction and the main plane of extension of the carrier are employed.

This setup has the advantage that both the radiation source and the sensor can be arranged on the same carrier. Thus, only one carrier or one PCB is required. Furthermore, the main plane of extension of the radiation source extends parallel to the main plane of extension of the sensor. This means, the radiation source and the sensor can be arranged in a flat and thus compact way on the carrier. It is not necessary that the sensor is tilted in order to detect electromagnetic radiation emitted by the radiation source. Instead, the deflection element is employed to deflect the electromagnetic radiation towards the sensor. This setup enables a compact, this means small, setup of the optoelectronic device. Moreover, the optoelectronic device can be surface mountable.

Another advantage is that electromagnetic radiation emitted by the radiation source is directly transmitted towards the sensor. This means, not stray radiation or indirect radiation but electromagnetic radiation directly emitted by the radiation source is detected by the sensor. The electromagnetic radiation directly emitted by the radiation source has a higher intensity than stray radiation which leads to a larger signal detected by the sensor. Thus, the accuracy of the data determined by the sensor is improved. Furthermore, the losses during detecting electromagnetic radiation emitted by the radiation source are minimized, since no absorbing elements are required but the electromagnetic radiation is only reflected.

According to at least one embodiment of the optoelectronic device, the deflection element is configured to change the main propagation direction of electromagnetic radiation impinging on the deflection element by 90°. This can be achieved by the deflection surface enclosing an angle of 45° with the main plane of extension of the sensor. For example, the sensor and the deflection surface are arranged above each other along the vertical direction. After changing the main propagation direction of electromagnetic radiation impinging on the deflection element by 90°, the main propagation direction of the deflected electromagnetic radiation runs parallel to the vertical direction. Thus, the deflected electromagnetic radiation reaches the sensor under an angle of 90° with respect to the main plane of extension of the sensor. This enables that the deflected electromagnetic radiation is detected by the sensor as most sensors are only sensitive to electromagnetic radiation reaching the sensor under certain angles, this can mean angles within a particular cone. Thus, to ensure a proper and correct measurement of the sensor it is necessary that electromagnetic radiation reaching the sensor only comprises electromagnetic radiation with a main propagation direction lying within a particular range of angles with respect to the main plane of extension of the sensor. This range of angles of the main propagation direction of the electromagnetic radiation can be arranged within a cone whose tip points towards the sensor. The opening angle of the cone can be 20° at most or 10° at most. This limited range of incoming angles of electromagnetic radiation is for example required for sensors comprising interference or dichroic filters.

According to at least one embodiment of the optoelectronic device, the deflection surface of the deflection element encloses an angle of at least 30° and at most 60° with the main plane of extension of the sensor. For this range of angles it is possible that electromagnetic radiation emitted by the radiation source is directed towards the sensor. At the same time, the electromagnetic radiation directed towards the sensor reaches the sensor under an angle that allows the sensor to detect the electromagnetic radiation for most types of sensors. This means, the electromagnetic radiation reaches the sensor under an angle that is large enough so that the sensor is sensitive to the electromagnetic radiation. For example, the electromagnetic radiation reaches the sensor under an angle of at least 80° with respect to the main plane of extension of the sensor.

According to at least one embodiment of the optoelectronic device, the deflection surface of the deflection element has a reflection coefficient of at least 0.5 for electromagnetic radiation emitted by the radiation source. It is also possible that the deflection surface has a reflection coefficient at least 0.8 or at least 0.9 for electromagnetic radiation emitted by the radiation source. This means, the deflection surface has a high reflectivity for electromagnetic radiation emitted by the radiation source. This enables that a large amount of electromagnetic radiation impinging on the deflection element is deflected towards the sensor. Thus, the intensity of electromagnetic radiation reaching the sensor can be increased by employing the deflection surface with a high reflectivity which leads to a higher sensor signal of the sensor. The higher the sensor signal is, the more accurate is the measurement of the sensor.

According to at least one embodiment of the optoelectronic device, the deflection element comprises a mirror. The deflection surface can be formed by the mirror or by a part of the mirror. The mirror can have a flat surface. This means, the mirror has a main plane of extension. The main plane of extension of the mirror can enclose an angle of at least 30° and at most 60° with the main plane of extension of the sensor. It is also possible that the mirror is a free-form mirror. That the deflection element comprises a mirror has the advantage that electromagnetic radiation impinging on the deflection element can be deflected towards the sensor.

According to at least one embodiment of the optoelectronic device, the sensor has a radiation-sensitive region with a main plane of extension that extends parallel to the main plane of extension of the radiation source. The radiation-sensitive region is sensitive to electromagnetic radiation. Thus, the radiation-sensitive region is employed to detect electromagnetic radiation. The radiation-sensitive region can be arranged within the sensor. The main plane of extension of the radiation-sensitive region can extend parallel to the main plane of extension of the sensor. This has the advantage that it is not necessary to tilt the radiation-sensitive region with respect to the main plane of extension of the radiation source. This enables to arrange the radiation source and the sensor adjacent to each other on the carrier and the optoelectronic device can have a compact setup.

According to at least one embodiment of the optoelectronic device, the deflection element is arranged within a housing comprising an opening. The deflection element can be fixed to the housing in a mechanical way or by an adhesive. The housing can be arranged on the carrier. The opening can face the radiation source. This can mean, that the opening is arranged in such a way that a part of the electromagnetic radiation emitted by the radiation source can reach the opening. Employing the housing with the opening enables that the electromagnetic radiation reaching the sensor is restricted to certain angles of the main propagation direction of the electromagnetic radiation. For example, only electromagnetic radiation with a main propagation direction lying within a cone with an opening angle of 10° at most can enter the opening. This can be achieved by designing the size of the opening to be small enough.

According to at least one embodiment of the optoelectronic device, the opening is connected with a channel arranged within the housing, wherein the channel has a main extension direction that runs parallel to the main plane of extension of the sensor. The channel can extend between the opening and the deflection element. Thus, electromagnetic radiation entering the housing through the opening can propagate through the channel towards the deflection element. Since the main extension direction of the channel runs parallel to the main plane of extension of the sensor, the electromagnetic radiation passing the opening can travel through the channel towards the deflection element. The opening and the channel enable that the electromagnetic radiation reaching the sensor is restricted to certain incidence angles of the electromagnetic radiation on the sensor. Only electromagnetic radiation with a main propagation direction that encloses a limited range of angles with the main plane of extension of the sensor can pass the opening and the channel towards the deflection element. For example, only electromagnetic radiation with a main propagation direction lying within a cone with an opening angle of 10° at most can pass the opening and the channel. This can be achieved by designing the size of the opening and the channel to be small enough to enable this condition.

According to at least one embodiment of the optoelectronic device, the sensor is arranged within the housing. The housing can comprise a cavity within which the sensor is arranged. The housing and the sensor can be aligned with respect to each other via solder pads. Once the sensor is arranged within the housing, it can be completely covered by the housing. Thus, the housing can be employed to control which electromagnetic radiation reaches the sensor. The amount of ambient radiation reaching the sensor can be reduced since only electromagnetic radiation passing through the opening and the channel can reach the sensor. According to at least one embodiment of the optoelectronic device, at least one surface of the housing has a reflection coefficient of at least 0.5. For example, a surface of the housing facing the radiation source has a reflection coefficient of at least 0.5. It is also possible that the housing has at least one surface that has a reflection coefficient at least 0.8 or at least 0.9. This can mean, that at least one surface of the housing has a high reflectivity. In this way, electromagnetic radiation emitted by the radiation source that does not pass through the opening but that hits the housing can be reflected by the housing. This has the advantage that the losses in brightness of the optoelectronic device are reduced. Most of the electromagnetic radiation reaching the housing is reflected at the housing so that it can be emitted by the optoelectronic device. Thus, the impact of the housing with the deflection element on the system performance of the optoelectronic device is minimized. It is also possible that each surface of the housing has a reflection coefficient of at least 0.5, of at least 0.8 or of at least 0.9.

According to at least one embodiment of the optoelectronic device, the optoelectronic device comprises at least one further radiation source. The further radiation source can have the same features as the radiation source. It is possible that the optoelectronic device comprises a plurality of further radiation sources. The radiation source and the further radiation sources can be arranged in a one-dimensional arrangement or in a two-dimensional arrangement on the carrier. The deflection element can be configured to deflect electromagnetic radiation emitted by the further radiation source towards the sensor. Thus, the sensor can be employed to detect electromagnetic radiation emitted by the further radiation source in the same way as for the radiation source. In this way, it is possible to monitor the electromagnetic radiation emitted by at least two radiation sources of the optoelectronic device, namely the radiation source and the further radiation source.

According to at least one embodiment of the optoelectronic device, the optoelectronic device comprises at least one further deflection element, wherein the further deflection element is arranged closer to the further radiation source than the deflection element. The further deflection element can have the same features as the deflection element. It is possible that the optoelectronic device comprises a plurality of further deflection elements. The deflection element and the further deflection element can be arranged within the same housing. The further deflection elements can be used in the same way as the deflection element for deflecting electromagnetic radiation. The sensor or a further sensor can be employed for detecting electromagnetic radiation emitted by the further radiation source. The optoelectronic device can comprise one or more than one further sensor. The further sensors can be arranged in a one-dimensional arrangement. That the further deflection element is arranged closer to the further radiation source than the deflection element can mean that the distance between the further deflection element and the further radiation source is smaller than the distance between the deflection element and the further radiation source. Employing a further deflection element and a further radiation source enables to arrange a plurality of further radiation sources and a plurality of further deflection elements in a compact way on the carrier.

If the radiation source and the further radiation sources are arranged in a two-dimensional arrangement, the sensor can be arranged in the center of the two-dimensional arrangement. Via the deflection element and the further deflection elements electromagnetic radiation emitted by the radiation source and the further radiation sources can be deflected towards the sensor. In this way, it is possible to monitor the electromagnetic radiation emitted by an array of radiation sources. Multiplexing can be employed to distinguish between electromagnetic radiation emitted from different radiation sources.

According to at least one embodiment of the optoelectronic device, the radiation source is configured to emit electromagnetic radiation of wavelengths within a range of wavelengths, wherein the range has an extension of 100 nm at most. This can mean, that wavelengths of electromagnetic radiation emitted by the radiation source differ from each other by 100 nm at most. The full width at half maximum of electromagnetic radiation emitted by the radiation source can be 100 nm at most. It is also possible that the full width at half maximum of electromagnetic radiation emitted by the radiation source is 50 nm at most. For this small range of wavelengths it is necessary to monitor the wavelength of electromagnetic radiation emitted by the radiation source. This is possible by employing the deflection element and the sensor.

Furthermore, a method for operating an optoelectronic device is provided. The optoelectronic device can preferably be operated by the method for operating an optoelectronic device described herein. This means all features disclosed for the optoelectronic device are also disclosed for the method for operating an optoelectronic device and vice-versa.

According to at least one embodiment of the method for operating an optoelectronic device, the method comprises emitting electromagnetic radiation by a radiation source of the optoelectronic device.

According to at least one embodiment of the method for operating an optoelectronic device, the method comprises deflecting electromagnetic radiation emitted by the radiation source towards a sensor of the optoelectronic device. The electromagnetic radiation can be deflected by or at the deflection element of the optoelectronic device.

According to at least one embodiment of the method for operating an optoelectronic device, the method comprises detecting deflected electromagnetic radiation by the sensor. This can mean, that at least a part of the electromagnetic radiation emitted by the radiation source and deflected at the deflection element is detected by the sensor.

According to at least one embodiment of the method for operating an optoelectronic device, the radiation source and the sensor are arranged on a carrier.

According to at least one embodiment of the method for operating an optoelectronic device, the radiation source has a main plane of extension that extends parallel to a main plane of extension of the sensor.

According to at least one embodiment of the method for operating an optoelectronic device, the method comprises emitting electromagnetic radiation by a radiation source of the optoelectronic device, deflecting electromagnetic radiation emitted by the radiation source towards a sensor of the optoelectronic device, and detecting deflected electromagnetic radiation by the sensor, wherein the radiation source and the sensor are arranged on a carrier, and the radiation source has a main plane of extension that extends parallel to a main plane of extension of the sensor.

The method for operating an optoelectronic device has the same advantages as described for the optoelectronic device. Thus, the optoelectronic device employed in the method can have a compact setup.

According to at least one embodiment of the method for operating an optoelectronic device, electromagnetic radiation that is emitted by the radiation source and that has a main propagation direction which encloses an angle of less than 20° with the main plane of extension of the radiation source is deflected towards the sensor. It is possible that electromagnetic radiation that is emitted by the radiation source and that has a main propagation direction which encloses an angle of less than 10° with the main plane of extension of the radiation source is deflected towards the sensor. Thus, only electromagnetic radiation emitted under flat angles by the radiation source is employed for being deflected towards the sensor. This radiation is not required for most applications so that the presence of the sensor, the deflection element and the housing only has a very small impact on the system performance of the optoelectronic device.

The following description of figures may further illustrate and explain exemplary embodiments. Components that are functionally identical or have an identical effect are denoted by identical references. Identical or effectively identical components might be described only with respect to the figures where they occur first. Their description is not necessarily repeated in successive figures.

### BRIEF DESCRIPTION OF THE DRAWINGS

FIG. 1 shows an exemplary embodiment of the optoelectronic device and an exemplary embodiment of the method for operating an optoelectronic device is described with FIG. 1.

FIGS. 2 and 3 show a part of an exemplary embodiment of the optoelectronic device.

FIG. 4 shows an exemplary embodiment of the sensor.

FIG. 5 shows an exemplary embodiment of the housing.

FIG. 6 shows a top view on an exemplary embodiment of the sensor.

FIG. 7 shows a part of an exemplary embodiment of the optoelectronic device.

FIGS. 8, 9 and 10 show further exemplary embodiments of the optoelectronic device.

FIGS. 11, 12 and 13 show cross sections through further exemplary embodiments of the optoelectronic device.

### DETAILED DESCRIPTION

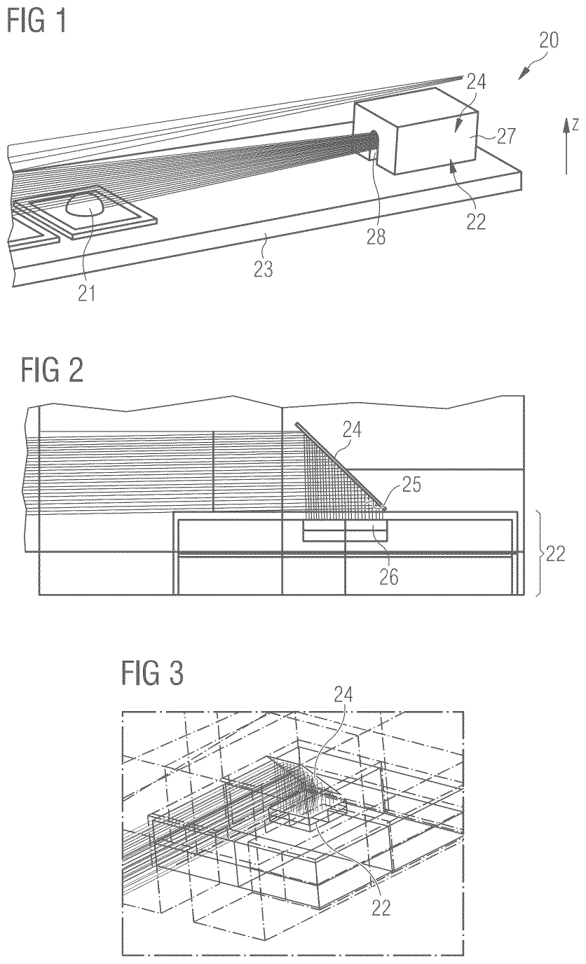

FIG. 1 shows an exemplary embodiment of the optoelectronic device 20. The optoelectronic device 20 comprises a radiation source 21 that is configured to emit electromagnetic radiation. The radiation source 21 is arranged on a carrier 23. The radiation source 21 can emit electromagnetic radiation in two different directions. In FIG. 1, as an example rays of electromagnetic radiation are depicted that propagate mainly in one direction. The radiation source 21 can be configured to emit electromagnetic radiation of wavelengths within a range of wavelengths, wherein the range has an extension of 100 nm at most.

The optoelectronic device 20 further comprises a sensor 22 that is configured to detect electromagnetic radiation. Also the sensor 22 is arranged on the carrier 23. In FIG. 1 the sensor 22 is not visible as it is arranged within a housing 27. The housing 27 is arranged on the carrier 23. Within the housing 27 a deflection element 24 is arranged. The deflection element 24 is arranged in such a way that the sensor 22 is arranged between the deflection element 24 and the carrier 23.

The radiation source 21 has a main plane of extension that extends parallel to a main plane of extension of the sensor 22, and the deflection element 24 has at least one deflection surface 25 that encloses an angle of more than 0° with the main plane of extension of the sensor 22. These features are not visible in FIG. 1 and are shown in other figures.

According to an exemplary embodiment of the method for operating optoelectronic device 20, the radiation source 21 emits electromagnetic radiation and a part of the emitted electromagnetic radiation is deflected towards the sensor 22. The sensor 22 then detects deflected electromagnetic radiation.

Electromagnetic radiation emitted by the radiation source 21 can reach an opening 28 of the housing 27. The electromagnetic radiation can enter the housing 27 through the opening 28. The electromagnetic radiation that enters the housing 27 through the opening 28 can reach the sensor 22 by being deflected by the deflection element 24.

Electromagnetic radiation that is emitted by the radiation source 21 and that has a main propagation direction which encloses an angle of less than 20° with the main plane of extension of the radiation source 21 is deflected towards the sensor 22. This is visible in FIG. 1 where only rays of electromagnetic radiation that enclose a small angle with the main plane of extension of the carrier 23 reach the opening 28. The amount of electromagnetic radiation emitted by the radiation source 21 and passing the opening 28 can be adapted by changing the extension of the opening 28 in a vertical direction z that extends perpendicular to the main plane of extension of the carrier 23. The larger the extension of the opening 28 in the vertical direction z is, the larger is the range of angles of main propagation directions of electromagnetic radiation that can pass the opening 28.

FIG. 2 shows a part of an exemplary embodiment of the optoelectronic device 20. A cross-section through the sensor 22 with the deflection element 24 is shown. The housing 27 is not shown in FIG. 2. A plurality of rays of electromagnetic radiation emitted by the radiation source 21 propagate from the left side of the figure towards the deflection element 24. At the deflection surface 25 the main propagation direction of the electromagnetic radiation is changed by 90°. This means, the deflection element 24 is configured to change the main propagation direction of electromagnetic radiation impinging on the deflection element 24 by 90°. Thus, the electromagnetic radiation is deflected towards the sensor 22.

For this purpose, the deflection surface 25 of the deflection element 24 encloses an angle of at least 30° and at most 60° with the main plane of extension of the sensor 22. Furthermore, the deflection surface 25 of the deflection element 24 can have a reflection coefficient of at least 0.5 for electromagnetic radiation emitted by the radiation source 21. It is also possible that the deflection element 24 comprises a mirror.

The sensor 22 has a radiation-sensitive region 26 with a main plane of extension that extends parallel to the main plane of extension of the radiation source 21. Thus, in FIG. 2 the main propagation direction of electromagnetic radiation reaching the sensor 22 and the main plane of extension of the radiation-sensitive region 26 enclose an angle of 90°.

FIG. 3 shows the same part of the optoelectronic device 20 as FIG. 2, but seen from a different angle. No cross-section through the sensor 22 is shown but a view on the sensor 22 with the deflection element 24.

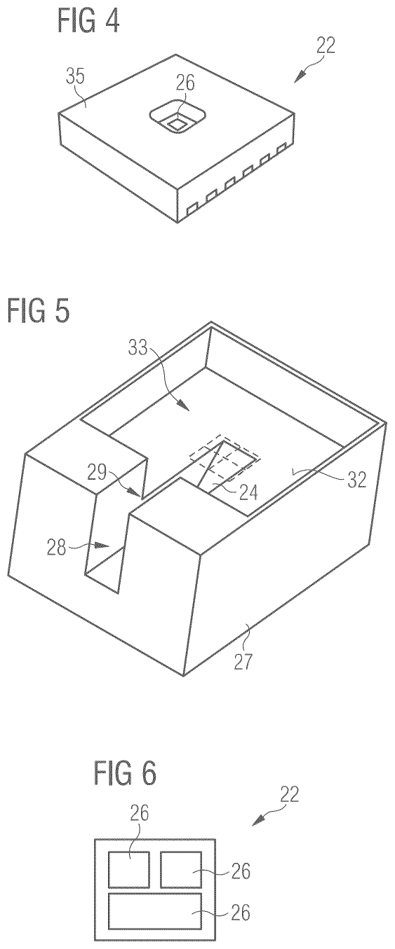

FIG. 4 shows an exemplary embodiment of the sensor 22. The sensor 22 comprises a package 35 within which the radiation-sensitive region 26 is arranged.

FIG. 5 shows an exemplary embodiment of the housing 27. The housing 27 is seen from a bottom side 32 of the housing 27. When mounted on the carrier 23, the bottom side 32 of the housing 27 faces the carrier 23. The opening 28 is connected with a channel 29 arranged within the housing 27, wherein the channel 29 has a main extension direction that runs parallel to the main plane of extension of the sensor 22. Adjacent to the channel 29 the deflection element 24 is arranged. The main plane of extension of the deflection element 24 is inclined with respect to the sidewalls of the channel 29. Adjacent to the deflection element 24 the housing 27 comprises a cavity 33 in which the sensor 22 is arranged once the housing 27 with the sensor 22 is mounted on the carrier 23. In FIG. 5 the cavity 33 is shown without the sensor 22. At least one surface of the housing 27 can have a reflection coefficient of at least 0.5, for example the surface adjacent to the opening 28.

FIG. 6 shows an exemplary embodiment of the sensor 22. The sensor 22 comprises three different radiation-sensitive regions 26. The three radiation-sensitive regions 26 can be sensitive to different wavelength ranges, respectively. The deflection surface 25 can be designed in such a way that electromagnetic radiation of a wavelength range is directed towards the respective radiation-sensitive region 26 that is sensitive to this wavelength range.

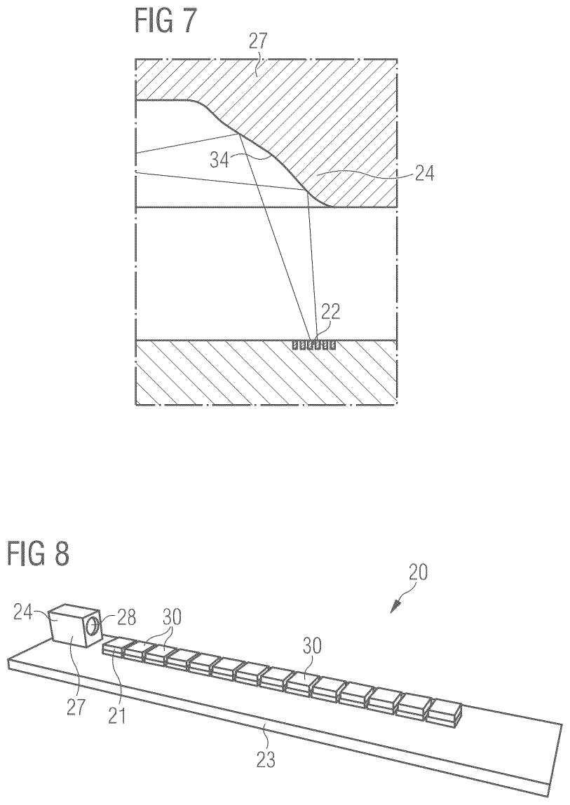

FIG. 7 shows a cross-section through a part of another exemplary embodiment of the optoelectronic device 20. A cross-section through the sensor 22 and a part of the housing 27 with the deflection element 24 is shown. The deflection element 24 comprises a free form mirror 34.

FIG. 8 shows another exemplary embodiment of the optoelectronic device 20. The optoelectronic device 20 comprises the radiation source 21 and a plurality of further radiation sources 30. The radiation source 21 and the plurality of further radiation sources 30 are arranged along a line. The housing 27 with the deflection element 24 is also arranged along the line. The radiation source 21 and the further radiation sources 30 are arranged at the same side of the housing 27. Electromagnetic radiation emitted by the radiation source 21 and by all further radiation sources 30 under angles of 20° at most with respect to the main plane of extension of the carrier 23 can reach the opening 28 and can thus be detected by the sensor 22. Thus, it is possible to monitor not only the emission of the radiation source 21 but also the emission of the further radiation sources 30 with the sensor 22.

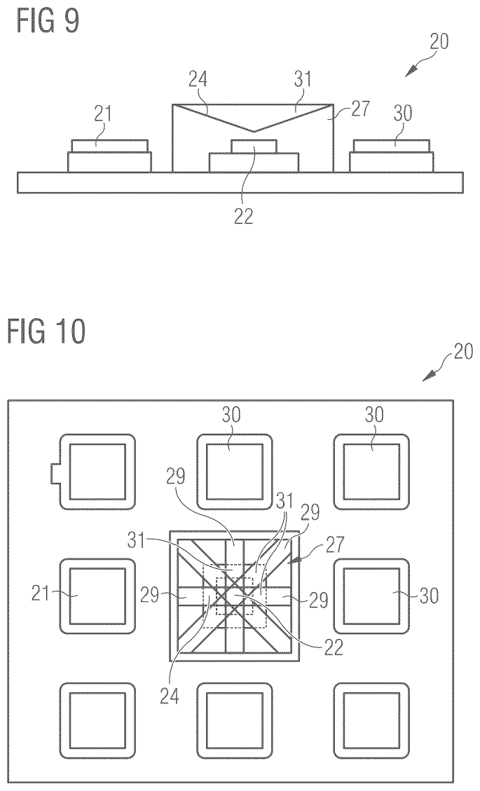

FIG. 9 shows a cross-section through another exemplary embodiment of the optoelectronic device 20. The optoelectronic device 20 comprises the radiation source 21 and at least one further radiation source 30. The radiation source 21 and the further radiation source 30 are arranged at different sides of the housing 27. The optoelectronic device 20 comprises the deflection element 24 and at least one further deflection element 31. The deflection element 24 faces the radiation source 21 and the further deflection element 31 faces the further radiation source 30. Both the deflection element 24 and the further deflection element 31 are arranged within the housing 27. The further deflection element 31 is arranged closer to the further radiation source 30 than the deflection element 24. Thus, it is possible that electromagnetic radiation emitted by the radiation source 21 is deflected by the deflection element 24 towards the sensor 22. It is also possible that electromagnetic radiation emitted by the further radiation source 30 is deflected by the further deflection element 31 towards the sensor 22. Thus, the sensor 22 can be employed to monitor electromagnetic radiation emitted by the radiation source 21 and electromagnetic radiation emitted by the further radiation source 30.

FIG. 10 shows a top view on another exemplary embodiment of the optoelectronic device 20. The optoelectronic device 20 shown in FIG. 9 can have the set up shown in FIG. 10. One radiation source 21 and seven further radiation sources 30 are arranged around the housing 27. The radiation source 21 and the further radiation sources 30 are arranged along the edges of a square. The housing 27 with the sensor 22 is arranged in the center of the square. Within the housing 27 one further deflection element 31 for each further radiation source 30 is arranged. This means, within the housing 27 the deflection element 24 and seven further deflection elements 31 are arranged. The further deflection elements 31 are arranged as shown in FIG. 9. The housing 27 can comprise eight channels 29 in total. Each channel 29 faces one of the radiation sources 21, 30. It is also possible that more further radiation sources 30 are arranged around the square formed by the further radiation sources 30 and the radiation source 21. It is possible that further radiation sources 30 extend along lines around the housing 27. The sensor 22 can be configured to determine from which radiation source 21 out of the radiation source 21 and the further radiation sources 30 detected electromagnetic radiation is coming.

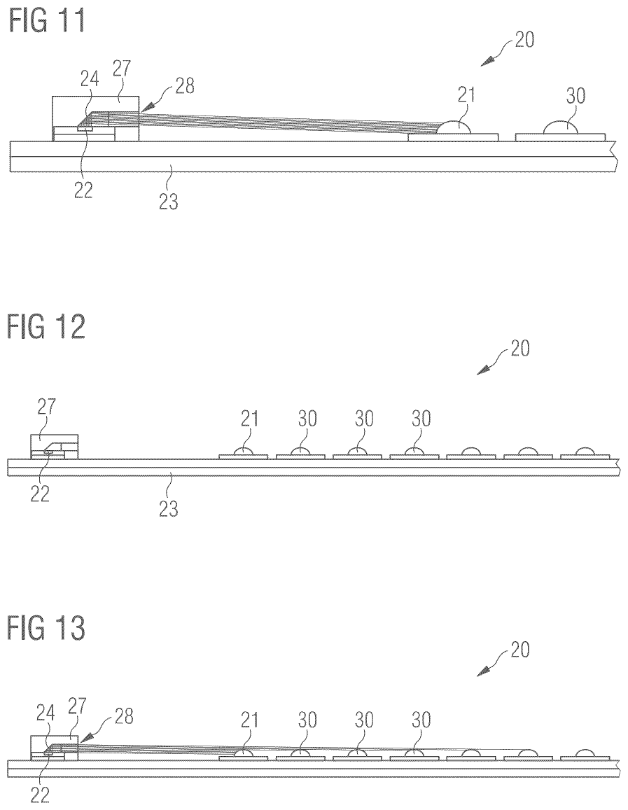

FIG. 11 shows a cross-section through another exemplary embodiment of the optoelectronic device 20. One radiation source 21 and one further radiation source 30 are arranged adjacent to each other on the carrier 23. As an example some rays of electromagnetic radiation emitted by the radiation source 21 are depicted in FIG. 11. These rays of electromagnetic radiation are emitted towards the housing 27 where they can enter the housing 27 through the opening 28. At the deflection element 24 the electromagnetic radiation is deflected towards the sensor 22.

FIG. 12 shows a cross-section through another exemplary embodiment of the optoelectronic device 20. One radiation source 21 and several further radiation sources 30 are arranged along a line on the carrier 23. The housing 27 with the sensor 22 is also arranged along the line. This enables, that the sensor 22 detects electromagnetic radiation emitted by the radiation source 21 and the further radiation sources 30.

FIG. 13 shows the same exemplary embodiment of the optoelectronic device 20 as FIG. 12. Furthermore, as an example some rays of electromagnetic radiation emitted by the radiation source 21 and the further radiation sources 30 are depicted. These rays propagate towards the housing 27 and can enter the housing 27 through the opening 28. At the deflection element 24 the electromagnetic radiation is deflected towards the sensor 22. Thus, with the sensor 22 electromagnetic radiation emitted by the radiation source 21 and by the further radiation sources 30 can be detected.

It will be appreciated that the disclosure is not limited to the disclosed embodiments and to what has been particularly shown and described hereinabove. Rather, features recited in separate dependent claims or in the description may advantageously be combined. Furthermore, the scope of the disclosure includes those variations and modifications, which will be apparent to those skilled in the art. The term “comprising”, insofar it was used in the claims or in the description, does not exclude other elements or steps of a corresponding feature or procedure. In case that the terms “a” or “an” were used in conjunction with features, they do not exclude a plurality of such features. Moreover, any reference signs in the claims should not be construed as limiting the scope.

1. An optoelectronic device comprising:
a radiation source that is configured to emit electromagnetic radiation,
a sensor that is configured to detect electromagnetic radiation,
a carrier on which the radiation source and the sensor are arranged, and
a deflection element, wherein
the sensor is arranged between the deflection element and the carrier,
the radiation source has a main plane of extension that extends parallel to a main plane of extension of the sensor,
the deflection element has at least one deflection surface that encloses an angle of more than 0° with the main plane of extension of the sensor,
the deflection element is arranged within a housing comprising an opening,
the opening is connected with a channel arranged within the housing, wherein the channel has a main extension direction that runs parallel to the main plane of extension of the sensor, and
the opening and the channel are provided such that only electromagnetic radiation that is emitted by the radiation source and that has a main propagation direction which encloses an angle of less than 20° with the main plane of extension of the radiation source can pass the opening and the channel towards the deflection element.

2. The optoelectronic device according to claim 1, wherein the deflection element is configured to change the main propagation direction of electromagnetic radiation impinging on the deflection element by 90°.

3. The optoelectronic device according to claim 1, wherein the deflection surface of the deflection element encloses an angle of at least 30° and at most 60° with the main plane of extension of the sensor.

4. The optoelectronic device according to claim 1, wherein the deflection surface of the deflection element has a reflection coefficient of at least 0.5 for electromagnetic radiation emitted by the radiation source.

5. The optoelectronic device according to claim 1, wherein the deflection element comprises a mirror.

6. The optoelectronic device according to claim 1, wherein the sensor has a radiation-sensitive region with a main plane of extension that extends parallel to the main plane of extension of the radiation source.

7. (canceled)

8. (canceled)

9. The optoelectronic device according to claim 1, wherein the sensor is arranged within the housing.

10. The optoelectronic device according to claim 1, wherein at least one surface of the housing has a reflection coefficient of at least 0.5.

11. The optoelectronic device according to claim 1, wherein the optoelectronic device comprises at least one further radiation source.

12. The optoelectronic device according to claim 11, wherein the optoelectronic device comprises at least one further deflection element, wherein the further deflection element is arranged closer to the further radiation source than the deflection element.

13. The optoelectronic device according to claim 1, wherein the radiation source is configured to emit electromagnetic radiation of wavelengths within a range of wavelengths, wherein the range has an extension of 100 nm at most.

14. A method for operating the optoelectronic device of claim 1, the method comprising:
emitting electromagnetic radiation by the radiation source of the optoelectronic device,
deflecting, by the deflecting element, electromagnetic radiation emitted by the radiation source towards the sensor of the optoelectronic device, and
detecting deflected electromagnetic radiation by the sensor, wherein
electromagnetic radiation that is emitted by the radiation source and that has a main propagation direction which encloses an angle of less than 20° with the main plane of extension of the radiation source is deflected towards the sensor.

15. (canceled)

16. An optoelectronic device comprising:
a radiation source that is configured to emit electromagnetic radiation,
a sensor that is configured to detect electromagnetic radiation,
a carrier on which the radiation source and the sensor are arranged, and
a deflection element, wherein
the sensor is arranged between the deflection element and the carrier,
the radiation source has a main plane of extension that extends parallel to a main plane of extension of the sensor, and
the deflection element has at least one deflection surface that encloses an angle of more than 0° with the main plane of extension of the sensor.
